(19) United States
(12) Patent Application Publication
(10) Pub. No.: US 2025/0234716 A1
(43) Pub. Date: Jul. 17, 2025

(54) DISPLAY APPARATUS AND METHOD OF MANUFACTURING THE SAME

(71) Applicant: Samsung Display Co., Ltd., Yongin-si (KR)

(72) Inventors: Hyunsup Yoon, Yongin-si (KR); Jongwoo Kim, Yongin-si (KR); Changyeong Song, Yongin-si (KR); Soyoung Oh, Yongin-si (KR); Woosuk Jung, Yongin-si (KR); Jaeheung Ha, Yongin-si (KR)

(21) Appl. No.: 18/924,174

(22) Filed: Oct. 23, 2024

(30) Foreign Application Priority Data
Jan. 17, 2024 (KR) 10-2024-0007630

(51) Int. Cl. H10K 59/122; H10K 59/12; H10K 59/80

(52) U.S. Cl. CPC H10K 59/122; H10K 59/1201; H10K 59/873

(57) ABSTRACT

A display apparatus includes a substrate, a lower electrode located on the substrate, a pixel-defining layer located on the lower electrode and including a pixel opening through which a part of the lower electrode is exposed, an intermediate layer located on the lower electrode and including an emission layer, an upper electrode located on the intermediate layer, a first inorganic encapsulation layer located on the upper electrode, a second inorganic encapsulation layer located on the first inorganic encapsulation layer and located in the pixel opening of the pixel-defining layer, and a third inorganic encapsulation layer located on the second inorganic encapsulation layer, wherein the third inorganic encapsulation layer is located directly on the first inorganic encapsulation layer in an area overlapping the pixel-defining layer and is spaced apart from the first inorganic encapsulation layer in an area overlapping the pixel opening.

This application claims priority to Korean Patent Application No. 10⁻²⁰²⁴-0007630, filed on Jan. 17, 2024, and all the benefits accruing therefrom under 35 U.S.C. § 119, the content of which in its entirety is herein incorporated by reference.

### BACKGROUND

### 1. Field

The invention relates to a display apparatus, and more particularly to a display apparatus and a method of manufacturing the same.

### 2. Description of the Related Art

Display apparatuses visually display data. Recently, display apparatuses have been used for various purposes. Also, as thicknesses and weights of display apparatuses have decreased, the range of applications of display apparatuses has increased.

To implement a thin and light display apparatus, the display apparatus may encapsulate an emission area by using a thin-film encapsulation layer, instead of an encapsulation substrate formed of glass. The thin-film encapsulation layer may prevent penetration of impurities such as oxygen or moisture into a light-emitting element and may cover a display area of the display apparatus to planarize a top surface of the display area.

### SUMMARY

One or more embodiments include a display apparatus and a method of manufacturing the same. However, the embodiments disclosed herein are examples and do not limit the scope of the invention.

According to an embodiment, a display apparatus includes a substrate, a lower electrode located on the substrate, a pixel-defining layer located on the lower electrode and including a pixel opening through which a part of the lower electrode is exposed, an intermediate layer located on the lower electrode and including an emission layer, an upper electrode located on the intermediate layer, a first inorganic encapsulation layer located on the upper electrode, a second inorganic encapsulation layer located on the first inorganic encapsulation layer and located in the pixel opening, and a third inorganic encapsulation layer located on the second inorganic encapsulation layer, wherein the third inorganic encapsulation layer is spaced apart from the first inorganic encapsulation layer in an area overlapping the pixel opening and is located directly on the first inorganic encapsulation layer in an area overlapping the pixel-defining layer.

In an embodiment, a film density of the second inorganic encapsulation layer may be lower than a film density of the first inorganic encapsulation layer.

In an embodiment, a film density of the second inorganic encapsulation layer may be lower than a film density of the third inorganic encapsulation layer.

In an embodiment, the second inorganic encapsulation layer may not overlap the pixel-defining layer.

In an embodiment, the second inorganic encapsulation layer may fill the pixel opening of the pixel-defining layer.

In an embodiment, each of the first inorganic encapsulation layer and the third inorganic encapsulation layer may overlap the pixel opening and the pixel-defining layer.

In an embodiment, a film density of the first inorganic encapsulation layer may be in a range of about 2.6 g/cm³ to about 3.5 g/cm³.

In an embodiment, a film density of the second inorganic encapsulation layer may be in a range of about 1.6 g/cm³ to about 2.3 g/cm³.

In an embodiment, a film density of the third inorganic encapsulation layer may be in a range of about 2.6 g/cm³ to about 3.5 g/cm³.

In an embodiment, each of the first inorganic encapsulation layer and the second inorganic encapsulation layer may include a silicon element and a nitrogen element, wherein a ratio of the nitrogen element to the silicon element of the first inorganic encapsulation layer is less than a ratio of the nitrogen element to the silicon element of the second inorganic encapsulation layer.

In an embodiment, a refractive index of the first inorganic encapsulation layer may be greater than a refractive index of the second inorganic encapsulation layer.

According to an embodiment, a display apparatus includes a substrate, a first light-emitting element, a second light-emitting element, and a third light-emitting element, wherein each of the first light-emitting element, the second light-emitting element and the third light-emitting element are located on the substrate and configured to emit light of different colors, and an encapsulation layer located on the first to third light-emitting elements to encapsulate the first to third light-emitting elements. The encapsulation layer includes a first inorganic encapsulation layer located on the first to third light-emitting elements, a second inorganic encapsulation layer located on the first inorganic encapsulation layer and having a film density lower than a film density of the first inorganic encapsulation layer, and including a first inorganic encapsulation pattern overlapping the first light-emitting element, a second inorganic encapsulation pattern overlapping the second light-emitting element, and a third inorganic encapsulation pattern overlapping the third light-emitting element, and further including a third inorganic encapsulation layer located on the second inorganic encapsulation layer, wherein the first inorganic encapsulation pattern, the second inorganic encapsulation pattern, and the third inorganic encapsulation pattern are spaced apart from each other.

In an embodiment, each of the first to third light-emitting elements may include a lower electrode, an emission layer located on the lower electrode, and an upper electrode located on the emission layer, wherein the display apparatus further includes a pixel-defining layer including a first pixel opening through which a part of the lower electrode of the first light-emitting element is exposed, a second pixel opening through which a part of the lower electrode of the second light-emitting element is exposed, and a third pixel opening through which a part of the lower electrode of the third light-emitting element is exposed, wherein the first inorganic encapsulation pattern is located in the first pixel opening, the second inorganic encapsulation pattern is located in the second pixel opening, and the third inorganic encapsulation pattern is located in the third pixel opening.

In an embodiment, each of the first to third inorganic encapsulation patterns may not overlap the pixel-defining layer.

In an embodiment, the third inorganic encapsulation layer may be spaced apart from the first inorganic encapsulation layer in an area overlapping the first to third pixel openings and may be located directly on the first inorganic encapsulation layer in an area overlapping the pixel-defining layer.

In an embodiment, each of the first inorganic encapsulation layer and the third inorganic encapsulation layer may overlap the first to third pixel openings and the pixel-defining layer.

In an embodiment, a film density of the third inorganic encapsulation layer may be greater than a film density of the second inorganic encapsulation layer.

According to an embodiment, a method of manufacturing a display apparatus includes forming, on a lower electrode, a pixel-defining layer having a pixel opening through which a part of the lower electrode is exposed, forming an emission layer on the lower electrode, forming an upper electrode on the emission layer, forming a first inorganic encapsulation layer on the upper electrode, forming a second inorganic encapsulation layer on the first inorganic encapsulation layer to fill the pixel opening by using a mask having an opening located in an area overlapping the pixel opening, and forming a third inorganic encapsulation layer on the second inorganic encapsulation layer, wherein a film density of the second inorganic encapsulation layer is lower than a film density of the first inorganic encapsulation layer.

In an embodiment, the third inorganic encapsulation layer may be spaced apart from the first inorganic encapsulation layer in the area overlapping the pixel opening and may be located directly on the first inorganic encapsulation layer in an area overlapping the pixel-defining layer.

In an embodiment, a deposition rate of the second inorganic encapsulation layer may be greater than a deposition rate of the first inorganic encapsulation layer.

In an embodiment, a deposition rate of the third inorganic encapsulation layer may be less than a deposition rate of the second inorganic encapsulation layer.

In an embodiment, a film density of the second inorganic encapsulation layer may be lower than a film density of the first inorganic encapsulation layer.

In an embodiment, a film density of the second inorganic encapsulation layer may be lower than a film density of the third inorganic encapsulation layer.

### BRIEF DESCRIPTION OF THE DRAWINGS

The above and other aspects, features, and advantages of the invention will be more apparent from the following description taken in conjunction with the accompanying drawings, in which:

FIG. 1 is a perspective view illustrating a display apparatus, according to an embodiment;

FIG. 2A is an equivalent circuit diagram illustrating a pixel included in a display apparatus, according to an embodiment;

FIG. 2B is an equivalent circuit diagram illustrating a pixel included in a display apparatus, according to an embodiment;

FIG. 3 is a cross-sectional view schematically illustrating a display apparatus, according to an embodiment;

FIG. 4A is a cross-sectional view schematically illustrating a method of manufacturing a display apparatus, according to an embodiment;

FIG. 4B is a cross-sectional view schematically illustrating a method of manufacturing a display apparatus, according to an embodiment;

FIG. 4C is a cross-sectional view schematically illustrating a method of manufacturing a display apparatus, according to an embodiment;

FIG. 4D is a cross-sectional view schematically illustrating a method of manufacturing a display apparatus, according to an embodiment; and

FIG. 4E is a cross-sectional view schematically illustrating a method of manufacturing a display apparatus, according to an embodiment.

### DETAILED DESCRIPTION

Reference will now be made in detail to the invention, embodiments and examples of which are illustrated in the accompanying drawings, wherein like reference numerals refer to like elements throughout. In this regard, the invention may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the scope of the invention allows for various changes and numerous embodiments, certain embodiments will be illustrated in the drawings and described in the detailed description. Effects and features of the invention, and methods for achieving them will be clarified with reference to embodiments described below in detail with reference to the drawings. However, the invention is not limited to the following embodiments and may be embodied in various forms.

Reference will now be made in detail to the invention, embodiments and examples of which are illustrated in the accompanying drawings, and in the drawings, the same elements are denoted by the same or similar reference numerals, and thus a repeated description thereof will be omitted.

Although the terms “first,” “second,” etc. may be used to describe various elements, these elements should not be limited by these terms. These terms are only used to distinguish one element from another.

As used herein, the singular forms “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

It will be further understood that, when a layer, region, or component is referred to as being “on” another layer, region, or component, it may be directly on the other layer, region, or component, or may be indirectly on the other layer, region, or component with intervening layers, regions, or components therebetween.

Furthermore sizes of components in the drawings may be exaggerated or reduced for convenience of explanation. For example, because sizes and thicknesses of components in the drawings are arbitrarily illustrated for convenience of explanation, the invention is not limited thereto.

When a certain embodiment may be implemented differently, a specific process order may be different from the described order. For example, two consecutively described processes may be performed substantially at the same time or may be performed in an order opposite to the described order.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

The x-axis, the y-axis and the z-axis are not limited to three axes of the rectangular coordinate system and may be interpreted in a broader sense. For example, the x-axis, the y-axis, and the z-axis may be directed perpendicular to one another, or may represent different directions that are not directed perpendicular to one another.

While such terms as “first” and “second” may be used to describe various elements, such elements must not be limited to the above terms. The above terms may be used to distinguish one element from another.

In the present specification, “A and/or B” means A or B, or A and B. In the present specification, “at least one of A and B” means A or B, or A and B.

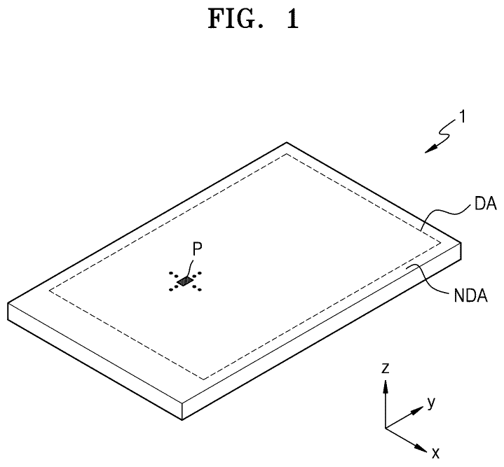

FIG. 1 is a perspective view illustrating a display apparatus 1, according to an embodiment.

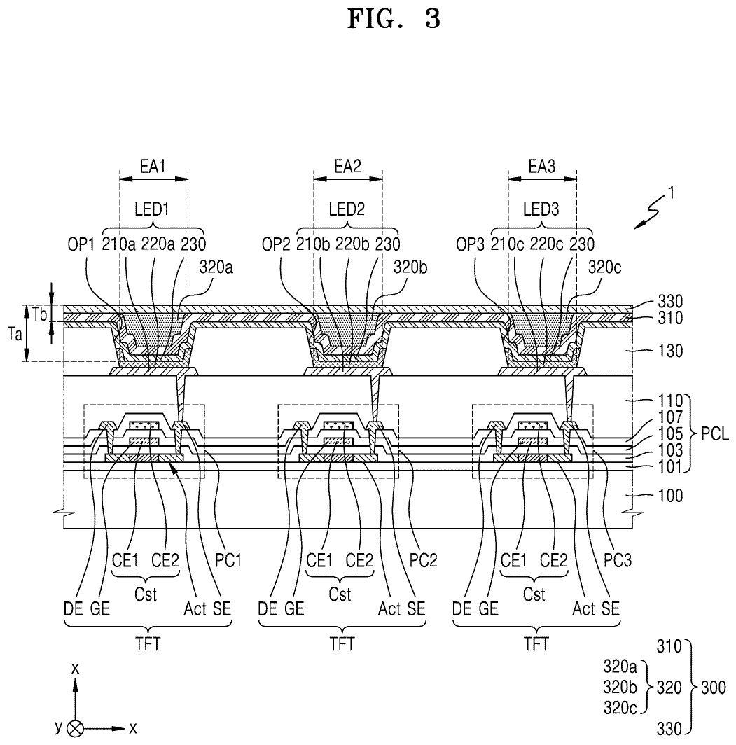

In an embodiment and referring to FIG. 1, the display apparatus 1 may include a display area DA where a plurality of pixels P are located and a non-display area NDA located outside of the display area DA. In detail, the non-display area NDA may entirely surround the display area DA. Accordingly, a substrate 100 (see FIG. 3) included in the display apparatus 1 may include the display area DA and the non-display area NDA.

In an embodiment, each pixel P of the display apparatus 1 is disposed in an area where light of a certain color may be emitted, and the display apparatus 1 may provide an image by using light emitted from the pixels P. For example, each pixel P may emit red light, green light, or blue light.

In an embodiment, the display area DA may have any polygonal shape, including a quadrangular shape as shown in FIG. 1. For example, the display area DA may have a rectangular shape in which a horizontal length is greater than a vertical length, a rectangular shape in which a horizontal length is less than a vertical length, or a square shape. In another embodiment, the display area DA may have any of various shapes such as an elliptical shape or a circular shape. As such, the display area DA may have any shape suitable to the desired end purpose.

In an embodiment, the non-display area NDA may be an area where the pixels P are not located. A driver or the like for applying an electrical signal or power to the pixels P may be located in the non-display area NDA. Pads (not shown) to which various electronic devices or printed circuit boards may be electrically connected may be located in the non-display area NDA. The pads may be located in the non-display area NDA and may be spaced apart from each other and may each be electrically connected to a printed circuit board or an integrated circuit board.

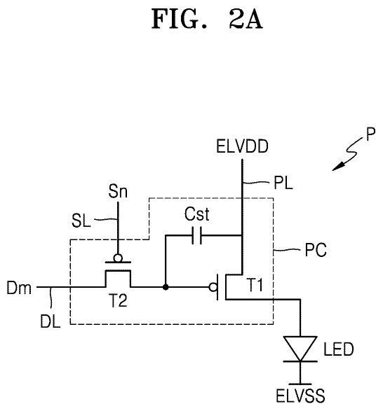

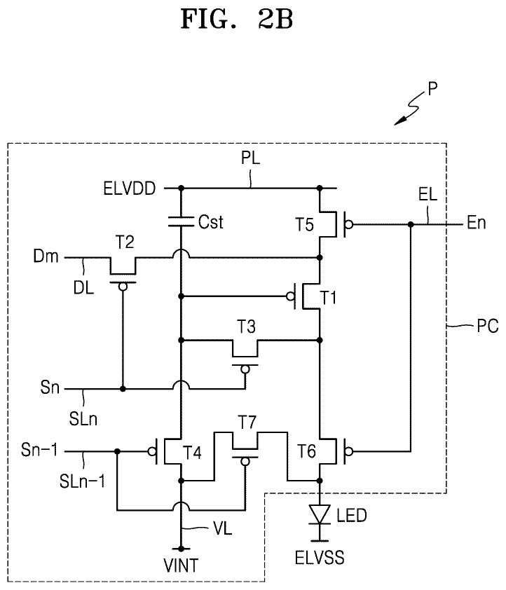

FIGS. 2A and 2B are equivalent circuit diagrams illustrating one pixel P included in the display apparatus 1, according to an embodiment.

In an embodiment and referring to FIG. 2A, each pixel P may include a pixel circuit PC which is connected to a scan line SL and a data line DL, and a light-emitting element LED which is connected to the pixel circuit PC.

In an embodiment, the pixel circuit PC may include a driving thin-film transistor T1, a switching thin-film transistor T2, and a storage capacitor Cst.

The switching thin-film transistor T2 transmits a data signal Dm which is input through the data line DL according to a scan signal Sn which is input through the scan line SL to the driving thin-film transistor T1.

In an embodiment, the storage capacitor Cst is connected to the switching thin-film transistor T2 and a driving voltage line PL, and stores a voltage corresponding to a difference between a voltage received from the switching thin-film transistor T2 and a first power supply voltage ELVDD (or a driving voltage) supplied to the driving voltage line PL.

In an embodiment, the driving thin-film transistor T1 may be connected to the driving voltage line PL and the storage capacitor Cst, and may control the driving current flowing from the driving voltage line PL to the light-emitting element LED in response to a value of the voltage stored in the storage capacitor Cst. The light-emitting element LED may emit light having a certain luminance due to the driving current.

Although the pixel circuit PC is shown as including two thin-film transistors and one storage capacitor in FIG. 2A, the invention is not limited thereto.

In an embodiment and referring to FIG. 2B, the pixel circuit PC may include a driving thin-film transistor T1, a switching thin-film transistor T2, a compensation thin-film transistor T3, a first initialization thin-film transistor T4, a first emission control thin-film transistor T5, a second emission control thin-film transistor T6, and a second initialization thin-film transistor T7.

Although each pixel P is shown as including signal lines (e.g., SLn, SLn-1, EL, and DL), an initialization voltage line VL, and the driving voltage line PL in FIG. 2B, the invention is not limited thereto. In another embodiment, at least one of the signal lines (e.g., SLn, SLn-1, EL, and DL), and/or the initialization voltage line VL may be shared by neighboring pixels.

In an embodiment, a drain electrode of the driving thin-film transistor T1 may be electrically connected to the light-emitting diode LED via the second emission control thin-film transistor T6. The driving thin-film transistor T1 receives a data signal Dm and supplies driving current to the light-emitting element LED according to a switching operation of the switching thin-film transistor T2.

In an embodiment, a gate electrode of the switching thin-film transistor T2 is connected to a first scan line SLn, and a source electrode of the switching thin-film transistor T2 is connected to the data line DL. A drain electrode of the switching thin-film transistor T2 may be connected to a source electrode of the driving thin-film transistor T1, and may be connected to the driving voltage line PL via the first emission control thin-film transistor T5.

The switching thin-film transistor T2 is turned on according to a first scan signal Sn which is received through the first scan line SLn and performs a switching operation of transmitting the data signal Dm which is received through the data line DL to the source electrode of the driving thin-film transistor T1.

In an embodiment, a gate electrode of the compensation thin-film transistor T3 may be connected to the first scan line SLn. A source electrode of the compensation thin-film transistor T3 may be connected to the drain electrode of the driving thin-film transistor T1 and may be connected to a pixel electrode of the light-emitting diode LED via the second emission control thin-film transistor T6. A drain electrode of the compensation thin-film transistor T3 may be connected to one electrode of the storage capacitor Cst, a source electrode of the first initialization thin-film transistor T4, and a gate electrode of the driving thin-film transistor T1. The compensation thin-film transistor T3 is turned on according to the first scan signal Sn which is received through the first scan line SLn, and diode-connects the driving thin-film transistor T1 by connecting the gate electrode and the drain electrode of the driving thin-film transistor T1.

In an embodiment, a gate electrode of the first initialization thin-film transistor T4 may be connected to a second scan line (previous scan line) SLn-1. A drain electrode of the first initialization thin-film transistor T4 may be connected to the initialization voltage line VL. The source electrode of the first initialization thin-film transistor T4 may be connected to one electrode of the storage capacitor Cst, the drain electrode of the compensation thin-film transistor T3, and the gate electrode of the driving thin-film transistor T1. The first initialization thin-film transistor T4 may be turned on according to a second scan signal Sn-1 which is received through the second scan line SLn-1, and which may perform an initialization operation of initializing a voltage of the gate electrode of the driving thin-film transistor T1 by supplying an initialization voltage VINT to the gate electrode of the driving thin-film transistor T1.

In an embodiment, a gate electrode of the first emission control thin-film transistor T5 may be connected to an emission control line EL. A source electrode of the first emission control thin-film transistor T5 may be connected to the driving voltage line PL. A drain electrode of the first emission control thin-film transistor T5 is connected to the source electrode of the driving thin-film transistor T1 and the drain electrode of the switching thin-film transistor T2.

In an embodiment, a gate electrode of the second emission control thin-film transistor T6 may be connected to the emission control line EL. A source electrode of the second emission control thin-film transistor T6 may be connected to the drain electrode of the driving thin-film transistor T1 and the source electrode of the compensation thin-film transistor T3. A drain electrode of the second emission control thin-film transistor T6 may be electrically connected to the pixel electrode of the light-emitting diode LED. The first emission control thin-film transistor T5 and the second emission control thin-film transistor T6 are simultaneously turned on according to an emission control signal En which is received through the emission control line EL, and thus, a first power supply voltage ELVDD is supplied to the light-emitting diode LED to cause a driving current to flow through the light-emitting diode LED.

In an embodiment, t gate electrode of the second initialization thin-film transistor T7 may be connected to the second scan line SLn-1. A source electrode of the second initialization thin-film transistor T7 may be connected to the pixel electrode of the light-emitting element LED. A drain electrode of the second initialization thin-film transistor T7 may be connected to the initialization voltage line VL. The second initialization thin-film transistor T7 may be turned on according to the second scan signal Sn-1 which is received through the second scan line SLn-1 and may initialize the pixel electrode of the light-emitting diode LED.

Although the first initialization thin-film transistor T4 and the second initialization thin-film transistor T7 are shown as being connected to the second scan line SLn-1 in FIG. 2B, according to an embodiment, the invention is not limited thereto. In another embodiment, the first initialization thin-film transistor T4 may be connected to the second scan line SLn-1, which is a previous scan line, to be driven according to the second scan signal Sn-1, and the second initialization thin-film transistor T7 may be connected to a separate signal line (e.g., a next scan line), to be driven according to a signal transmitted to the separate scan line.

In an embodiment, one electrode of the storage capacitor Cst may be connected to the driving voltage line PL. The other electrode of the storage capacitor Cst may be connected to the gate electrode of the driving thin-film transistor T1, the drain electrode of the compensation thin-film transistor T3, and the source electrode of the first initialization thin-film transistor T4.

A counter electrode (e.g., a cathode) of the light-emitting diode LED receives a second power supply voltage ELVSS (or a common power supply voltage). Accordingly, the light-emitting element LED receives a driving current from the driving thin-film transistor T1 to emit light.

The pixel circuit PC is not limited to the number of thin-film transistors and storage capacitors and a circuit design described with reference to FIGS. 2A and 2B and, in other embodiments, the number and the circuit design may be modified in various ways.

FIG. 3 is a cross-sectional view schematically illustrating the display apparatus 1, according to an embodiment.

In an embodiment and referring to FIG. 3, the display apparatus 1 may include the substrate 100, a pixel circuit layer PCL disposed on the substrate 100, first to third light-emitting elements LED1, LED2, and LED3, respectively, disposed on the pixel circuit layer PCL, and an encapsulation layer 300 disposed on the light-emitting elements LED1, LED2, and LED3.

In an embodiment, the substrate 100 may include glass, a metal, or a polymer resin. The polymer resin may include, for example, polyethersulfone, polyacrylate, polyetherimide, polyethylene naphthalate, polyethylene terephthalate, polyphenylene sulfide, polyarylate, polyimide, polycarbonate, cellulose acetate propionate, or a mixture thereof. However, in other embodiments, various modifications may be made. For example, in another embodiment, the substrate 100 may have a multi-layer structure including two layers each including a polymer resin and a barrier layer including an inorganic material (e.g., silicon oxide (SiOₓ), silicon nitride (SiNₓ), or silicon oxynitride (SiOₓN_{y}) and located between the two layers.

In an embodiment, the pixel circuit layer PCL may include a first pixel circuit PC1, a second pixel circuit PC2 and a third pixel circuit PC3. Each of the pixel circuits PC1, PC2, and PC3 may include a transistor and a storage capacitor as described with reference to FIG. 2A or 2B. In an embodiment, FIG. 3 illustrates a thin-film transistor TFT and a storage capacitor Cst provided in each of the pixel circuits PC1, PC2, and PC3.

In an embodiment, the pixel circuit layer PCL may include a buffer layer 101, a first insulating layer 103, a second insulating layer 105, a third insulating layer 107, the thin-film transistor TFT, and a fourth insulating layer 110.

In an embodiment, the buffer layer 101 may be located on the substrate 100 to planarize a top surface of the substrate 100 and to block penetration of impurities from the substrate 100. The buffer layer 101 may include an inorganic insulating material such as silicon oxide (SiOₓ), silicon nitride (SiNₓ), or silicon oxynitride (SiOₓN_{y}). The buffer layer 101 may have a single or multi-layer structure including the above inorganic insulating material.

In an embodiment, each of the first to third pixel circuits PC1, PC2, and PC3 may include one thin-film transistor TFT and one storage capacitor Cst. The thin-film transistor TFT may include a semiconductor layer Act, a gate electrode GE, a source electrode SE, and a drain electrode DE.

In an embodiment, the semiconductor layer Act may be located on the buffer layer 101, wherein the semiconductor layer Act may include an oxide semiconductor and/or a silicon semiconductor. In an embodiment, when the semiconductor layer Act is formed of an oxide semiconductor, the semiconductor layer Act may include an oxide of at least one material selected from the group consisting of, for example, indium (In), gallium (Ga), tin (Sn), zirconium (Zr), vanadium (V), hafnium (Hf), cadmium (Cd), germanium (Ge), chromium (Cr), titanium (Ti), and zinc (Zn). For example, the semiconductor layer Act may be an InSnZnO (ITZO) semiconductor layer or an InGaZnO (IGZO) semiconductor layer. In another embodiment, when the semiconductor layer Act is formed of a silicon semiconductor, the semiconductor layer Act may include, for example, amorphous silicon or low temperature polysilicon (LTPS).

In an embodiment, the gate electrode GE may be located on the semiconductor layer Act with the first insulating layer 103 disposed therebetween. The gate electrode GE may overlap a channel region of the semiconductor layer Act. The gate electrode GE may include a low-resistance metal material. For example, in an embodiment, the gate electrode GE may have a single or multi-layer structure including at least one metal selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The gate electrode GE may be connected to a gate line that applies an electrical signal to the gate electrode GE.

In an embodiment, the first insulating layer 103 may be located on the buffer layer 101 and may be located between the semiconductor layer Act and the gate electrode GE. The first insulating layer 103 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

In an embodiment, the second insulating layer 105 may be located on the first insulating layer 103 and may cover the gate electrode GE. The second insulating layer 105 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO), like the first insulating layer 103.

In an embodiment, a second capacitor electrode CE2 of the storage capacitor Cst may be located on the second insulating layer 105. In an embodiment, the second capacitor electrode CE2 may overlap the gate electrode GE. In this case, the gate electrode GE and the second capacitor electrode CE2 overlapping each other with the second insulating layer 105 disposed therebetween may constitute the storage capacitor Cst. That is, the gate electrode GE may function as a first capacitor electrode CE1 of the storage capacitor Cst. As such, the storage capacitor Cst and the thin-film transistor TFT may overlap each other. In another embodiment, the storage capacitor Cst and the thin-film transistor TFT may not overlap each other.

In an embodiment, the third insulating layer 107 may be located on the second insulating layer 105 and may cover the second capacitor electrode CE2. The third insulating layer 107 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The third insulating layer 107 may have a single or multi-layer structure including the above inorganic insulating material.

In an embodiment, each of the source electrode SE and the drain electrode DE may be located on the third insulating layer 107, where the source electrode SE and the drain electrode DE may be electrically connected to the semiconductor layer Act through contact holes that are formed in the first insulating layer 103, the second insulating layer 105, and the third insulating layer 107. The source electrode SE and the drain electrode DE may include a material having good conductivity. At least one of the source electrode SE and the drain electrode DE may include a conductive material including molybdenum (Mo), aluminum (Al), copper (Cu), or titanium (Ti), and may have a single or multi-layer structure including the above material. In an embodiment, at least one of the source electrode SE and the drain electrode DE may have a multi-layer structure including Ti/Al/Ti.

In an embodiment, the fourth insulating layer 110 may be located on the third insulating layer 107. The fourth insulating layer 110 may be further located on the source electrode SE and the drain electrode DE. Although the fourth insulating layer 110 is shown as having a single-layer structure, the invention is not limited thereto and, in another embodiment, the fourth insulating layer 110 may have a multi-layer structure. The fourth insulating layer 110 may be an organic insulating layer including an organic material. The fourth insulating layer 110 may include an organic insulating material such as a general-purpose polymer such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof. The fourth insulating layer 110 may planarize the top surfaces of the pixel circuits PC1, PC2, and PC3 to planarize the surfaces on which the light-emitting elements LED1, LED2, and LED3 are to be located.

In an embodiment, the light-emitting elements LED1, LED2, and LED3 may emit light of different colors. For example, the first light-emitting element LED1 may emit red light, the second light-emitting element LED2 may emit green light, and the third light-emitting element LED3 may emit blue light.

In an embodiment, the light-emitting elements LED1, LED2, and LED3 may be organic light-emitting diodes each including an organic emission layer. In another embodiment, the light-emitting elements LED1, LED2, and LED3 may be inorganic light-emitting elements each including an inorganic emission layer. The light-emitting elements LED1, LED2, and LED3 may be micro-scale or nano-scale light-emitting elements. For example, the light-emitting elements LED1, LED2, and LED3 may be micro light-emitting elements. In another embodiment, the light-emitting elements LED1, LED2, and LED3 may be nanorod light-emitting elements. The nanorod light-emitting element may include gallium nitride (GaN). In an embodiment, a color conversion layer may be located on each of the nanorod light-emitting elements. The color conversion layer may include quantum dots. In another embodiment, the light-emitting elements LED1, LED2, and LED3 may be quantum dot light-emitting diodes each including a quantum dot emission layer.

In an embodiment, the first light-emitting element LED1, the second light-emitting element LED2 and the third light-emitting element LED3 may be electrically connected to the first pixel circuit PC1, the second pixel circuit PC2 and the third pixel circuit PC3, respectively, and may be located between the substrate 100 and the light-emitting elements LED1, LED2, and LED3 along a direction (e.g., a z-direction) that is directed perpendicular to a top surface of the substrate 100.

In an embodiment, each of the light-emitting elements LED1, LED2, and LED3 may have a stacked structure including a lower electrode, an intermediate layer, and an upper electrode. The first lower electrode 210a, the second lower electrode 210b and the third lower electrode 210c of the first light-emitting diode LED1, the second light-emitting diode LED2 and the third light-emitting diode LED3, respectively, may be anodes and an upper electrode 230 may be a cathode, but the invention is not limited thereto. For example, in an embodiment, the light-emitting elements LED1, LED2, and LED3 may be inverted light-emitting elements. For example, in an embodiment, the first to third lower electrodes 210a, 210b, and 210c, respectively, may be cathodes and the upper electrode 230 may be an anode. For convenience of explanation, the following will be described assuming that the first to third lower electrodes 210a, 210b, and 210c, respectively, are anodes and the upper electrode 230 is a cathode.

In an embodiment, the first light-emitting element LED1 may include the first lower electrode 210a, a first intermediate layer 220a, and the upper electrode 230. The first lower electrode 210a may be electrically connected to the first pixel circuit PC1. The second light-emitting element LED2 may include the second lower electrode 210b, a second intermediate layer 220b, and the upper electrode 230. The second lower electrode 210b may be electrically connected to the second pixel circuit PC2. The third light-emitting element LED3 may include the third lower electrode 210c, a third intermediate layer 220c, and the upper electrode 230. The third lower electrode 210c may be electrically connected to the third pixel circuit PC3.

In an embodiment, the lower electrodes 210a, 210b, and 210c, respectively, may be located on the fourth insulating layer 110. The lower electrodes 210a, 210b, and 210c may be electrically connected to the thin-film transistors TFT respectively provided in the pixel circuits PC1, PC2, and PC3. For example, the first lower electrode 210a may be electrically connected to the thin-film transistor TFT of the first pixel circuit PC1 through a contact hole of the fourth insulating layer 110.

In an embodiment, each of the lower electrodes 210a, 210b, and 210c may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, each of the lower electrodes 210a, 210b, and 210c may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In still another embodiment, each of the lower electrodes 210a, 210b, and 210c may further include a film formed of ITO, IZO, ZnO, or In₂O₃ over/under the reflective film.

In an embodiment, a pixel-defining layer 130 may be located on the fourth insulating layer 110. The pixel-defining layer 130 may be located on the lower electrodes 210a, 210b, and 210c, and may include a first pixel opening OP1 through which a part of the first lower electrode 210a is exposed, a second pixel opening OP2 through which a part of the second lower electrode 210b is exposed, and a third pixel opening OP3 through which a part of the third lower electrode 210c is exposed. That is, at least parts of the surfaces of the first lower electrode 210a, the second lower electrode 210b and the third lower electrode 210c may be exposed through the first pixel opening OP1, the second pixel opening OP2 and the third pixel opening OP3, respectively, defined in the pixel-defining layer 130. In an embodiment, portions exposed through the first through third pixel openings OP1, OP2, and OP3, respectively, of the pixel-defining layer 130 may be defined as a first emission area EA1, a second emission area EA2 and a third emission area EA3, respectively. The pixel-defining layer 130 may include an organic insulating material and/or an inorganic insulating material.

In an embodiment, the first intermediate layer 220a, the second intermediate layer 220b and the third intermediate layer 220c may be respectively located in the first pixel opening OP1, the second pixel opening OP2 and the third pixel opening OP3 of the pixel-defining layer 130. The first intermediate layer 220a, the second intermediate layer 220b and the third intermediate layer 220c may be respectively located on the first lower electrode 210a, the second lower electrode 210b and the third lower electrode 210c. Each of the intermediate layers 220a, 220b, and 220c may include, for example, an emission layer. The emission layer may be, for example, an organic emission layer. The organic emission layer may include an organic material including a fluorescent or phosphorescent material that emits red, green, blue, or white light.

In an embodiment, the first intermediate layer 220a located between the first lower electrode 210a and the upper electrode 230 may emit light of a first color. The second intermediate layer 220b located between the second lower electrode 210b and the upper electrode 230 may emit light of a second color. The third intermediate layer 220c located between the third lower electrode 210c and the upper electrode 230 may emit light of a third color. For example, the intermediate layers 220a, 220b, and 220c may emit light of different colors.

In an embodiment, each of the intermediate layers 220a, 220b, and 220c may include a common layer located under and/or over the emission layer. The common layer may include a hole transport layer (HTL), a hole injection layer (HIL), an electron transport layer (ETL), and/or an electron injection layer (EIL) and may cover a plurality of lower electrodes, e.g., the lower electrodes 210a, 210b, and 210c, like the upper electrode 230. In other words, the upper electrode 230 and the common layer may be shared by the light-emitting diodes LED1, LED2, and LED3.

In an embodiment, the upper electrode 230 may be located on the intermediate layers 220a, 220b, and 220c and may entirely cover the substrate 100 in the display area DA (see FIG. 1). The upper electrode 230 may be a light-transmitting electrode or a reflective electrode and may be formed of a conductive material having a low work function. For example, in an embodiment, the upper electrode 230 may include a (semi-) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another embodiment, the upper electrode 230 may further include a layer formed of ITO, IZO, ZnO, or In₂O₃ on the (semi-) transparent layer including the above material.

In an embodiment, the encapsulation layer 300 may encapsulate the light-emitting elements LED1, LED2, and LED3, where the encapsulation layer 300 may be located on the light-emitting elements LED1, LED2, and LED3. The encapsulation layer 300 may include a plurality of inorganic encapsulation layers including an inorganic material. For example, the encapsulation layer 300 may include a first inorganic encapsulation layer 310 disposed on the upper electrode 230, a second inorganic encapsulation layer 320 disposed on the first inorganic encapsulation layer 310 and a third inorganic encapsulation layer 330 disposed on the second inorganic encapsulation layer 320. In an embodiment, the encapsulation layer 300 may not include an organic encapsulation layer including an organic material.

In an embodiment, each of the first inorganic encapsulation layer 310 and the third inorganic encapsulation layer 330 may entirely cover the substrate 100. For example, each of the first inorganic encapsulation layer 310 and the third inorganic encapsulation layer 330 may cover the light-emitting elements LED1, LED2, and LED3, like the upper electrode 230. For example, each of the first inorganic encapsulation layer 310 and the third inorganic encapsulation layer 330 may overlap the pixel openings OP1, OP2, and OP3 and may overlap the pixel-defining layer 130. That is, each of the first inorganic encapsulation layer 310 and the third inorganic encapsulation layer 330 may overlap the first emission area EA1, the second emission area EA2 and the third emission area EA3 defined by the first pixel opening OP1, the second pixel opening OP2 and the third pixel opening OP3, respectively, and may overlap the pixel-defining layer 130 located outside the emission areas EA1, EA2, and EA3.

In an embodiment, in an area overlapping the pixel openings OP1, OP2, and OP3, because the second inorganic encapsulation layer 320 is located between the first inorganic encapsulation layer 310 and the third inorganic encapsulation layer 330, the third inorganic encapsulation layer 330 may be spaced apart from the first inorganic encapsulation layer 310. In other words, the third inorganic encapsulation layer 330 may be spaced apart from the first inorganic encapsulation layer 310 in a direction (e.g., the z direction) that is perpendicular to the top surface of the substrate 100 in the emission areas EA1, EA2, and EA3. In the area overlapping the pixel openings OP1, OP2, and OP3, the encapsulation layer 300 may have a three-layer structure in which the first inorganic encapsulation layer 310, the second inorganic encapsulation layer 320, and the third inorganic encapsulation layer 330 are sequentially stacked.

In an embodiment, in an area overlapping the pixel-defining layer 130, the third inorganic encapsulation layer 330 may be located directly on the first inorganic encapsulation layer 310. In other words, in the area overlapping the pixel-defining layer 130, the third inorganic encapsulation layer 330 may contact the first inorganic encapsulation layer 310. As shown in FIG. 3, the encapsulation layer 300 may have a two-layer structure including the first inorganic encapsulation layer 310 and the third inorganic encapsulation layer 330 located in the area overlapping the pixel-defining layer 130. However, the invention is not limited thereto. In another embodiment, when the first inorganic encapsulation layer 310 and the third inorganic encapsulation layer 330 are deposited by using the same precursor under the same deposition condition (e.g., deposition method or deposition rate), the encapsulation layer 300 may have a single-layer structure in which the first inorganic encapsulation layer 310 and the third inorganic encapsulation layer 330 are combined with each other in the area overlapping the pixel-defining layer 130.

In an embodiment, the second inorganic encapsulation layer 320 may be located in each of the pixel openings OP1, OP2, and OP3. The second inorganic encapsulation layer 320 may overlap each of the pixel openings OP1, OP2, and OP3 and may not overlap the pixel-defining layer 130. The second inorganic encapsulation layer 320 may be located between the first inorganic encapsulation layer 310 and the third inorganic encapsulation layer 330 in each of the emission areas EA1, EA2, and EA3.

In an embodiment, the second inorganic encapsulation layer 320 may include a first inorganic encapsulation pattern 320a located in the first pixel opening OP1, a second inorganic encapsulation pattern 320b located in the second pixel opening OP2, and a third inorganic encapsulation pattern 320c located in the third pixel opening OP3. That is, the first inorganic encapsulation pattern 320a may be located in the first emission area EA1, the second inorganic encapsulation pattern 320b may be located in the second emission area EA2 and the third inorganic encapsulation pattern 320c may be located in the third emission area EA3. The first inorganic encapsulation pattern 320a may overlap the first light-emitting element LED1, the second inorganic encapsulation pattern 320b may overlap the second light-emitting element LED2, and the third inorganic encapsulation pattern 320c may overlap the third light-emitting element LED3. The inorganic encapsulation patterns 320a, 320b, and 320c may be spaced apart from each other in a first direction (e.g., an x direction).

In an embodiment, the second inorganic encapsulation layer 320 may have a structure filling each of the pixel openings OP, OP2, and OP3. The first inorganic encapsulation pattern 320a, the second inorganic encapsulation pattern 320b and the third inorganic encapsulation pattern 320c may overlap the first pixel opening OP1, the second pixel opening OP2 and the third pixel opening OP3, respectively, and may not overlap the pixel-defining layer 130.

Because the second inorganic encapsulation layer 320 is formed as a low-density layer as described below, the second inorganic encapsulation layer 320 may fill each of the pixel openings OP1, OP2, and OP3 of the pixel-defining layer 130. Because the second inorganic encapsulation layer 320 does not overlap the pixel-defining layer 130 and fills each of the pixel openings OP1, OP2, and OP3, a top surface of the second inorganic encapsulation layer 320 may be located at substantially the same level as a top surface of a part of the first inorganic encapsulation layer 310 located in the area overlapping the pixel-defining layer 130. Accordingly, a top surface of the encapsulation layer 300 may be planarized.

An embodiment may not include an organic encapsulation layer, unlike a comparative example where a top surface of the encapsulation layer 300 is planarized by forming an organic encapsulation layer entirely on the substrate 100 of the display area DA. Also, because a top surface of the encapsulation layer 300 is planarized by forming the second inorganic encapsulation layer 320 having a low density to overlap only the pixel openings OP1, OP2, and OP3, a thickness of the encapsulation layer 300 may be reduced, as compared to a case where an organic encapsulation layer is formed entirely on a top surface of the first inorganic encapsulation layer 310. That is, because a thickness Ta of the encapsulation layer 300 in the area overlapping the pixel openings OP1, OP2, and OP3 and a thickness Tb of the encapsulation layer 300 in the area overlapping the pixel-defining layer 130 are reduced, the display apparatus 1 having a small thickness may be provided.

For example, in an embodiment, in the area overlapping the pixel openings OP1, OP2, and OP3, the thickness Ta of the encapsulation layer 300 may be about 3 μm or less. For example, in an embodiment, in the area overlapping the pixel openings OP1, OP2, and OP3, the thickness Ta of the encapsulation layer 300 may be about 2 μm or less. For example, in an embodiment, in the area overlapping the pixel-defining layer 130, the thickness Tb of the encapsulation layer 300 may be about 1 μm or less. For example, in an embodiment, in the area overlapping the pixel-defining layer 130, the thickness Tb of the encapsulation layer 300 may be in the range of about 0.002 μm to about 0.02 μm. That is, a thickness of the encapsulation layer 300 located over the pixel-defining layer 130 may be as small as about 1 μm or less.

In an embodiment, a thickness of the second inorganic encapsulation layer 320 in a direction (e.g., a thickness direction or the z direction) perpendicular to the top surface of the substrate 100 may be greater than a thickness of the first inorganic encapsulation layer 310. For example, a thickness of the first inorganic encapsulation layer 310 may range from about 10 Å to about 100 Å, and a thickness of the second inorganic encapsulation layer 320 may be greater than about 100 Å. For example, a thickness of the third inorganic encapsulation layer 330 may range from, but not limited to, about 10 Å to about 100 Å.

In an embodiment, each of the first inorganic encapsulation layer 310, the second inorganic encapsulation layer 320, and the third inorganic encapsulation layer 330 may include an inorganic material. For example, each of the inorganic encapsulation layers 310, 320, and 330 may include an inorganic material such as silicon nitride (SiNₓ), silicon oxide (SiOₓ), or silicon oxynitride (SiOₓN_{y}).

In an embodiment, each of the inorganic encapsulation layers 310, 320, and 330 may include an inorganic material including a silicon (Si) element and a nitrogen (N) element. For example, each of the inorganic encapsulation layers 310, 320, and 330 may include silicon nitride (SiNₓ) or silicon oxynitride (SiOₓN_{y}).

In an embodiment, when each of the first inorganic encapsulation layer 310 and the second inorganic encapsulation layer 320 includes an inorganic material including a silicon (Si) element and a nitrogen (N) element, a ratio (N/Si ratio) of the nitrogen element to the silicon element of the first inorganic encapsulation layer 310 may be less than a ratio (N/Si ratio) of the nitrogen element to the silicon element of the second inorganic encapsulation layer 320. For example, a ratio of the nitrogen element to the silicon element of the first inorganic encapsulation layer 310 may be less than about 0.75, and a ratio of the nitrogen element to the silicon element of the second inorganic encapsulation layer 320 may be greater than about 0.77. When each of the third inorganic encapsulation layer 330 and the second inorganic encapsulation layer 320 includes an inorganic material including a silicon (Si) element and a nitrogen (N) element, a ratio (N/Si ratio) of the nitrogen element to the silicon element of the third inorganic encapsulation layer 330 may be less than a ratio (N/Si ratio) of the nitrogen element to the silicon element of the second inorganic encapsulation layer 320. For example, a ratio of the nitrogen element to the silicon element of the third inorganic encapsulation layer 330 may be less than about 0.75, and a ratio of the nitrogen element to the silicon element of the second inorganic encapsulation layer 320 may be greater than about 0.77.

In an embodiment, a film density of the first inorganic encapsulation layer 310 and a film density of the second inorganic encapsulation layer 320 may be different from each other. Additionally, a film density of the third inorganic encapsulation layer 330 and a film density of the second inorganic encapsulation layer 320 may be different from each other. A film density of the second inorganic encapsulation layer 320 may be less than a film density of the first inorganic encapsulation layer 310. That is, the first inorganic encapsulation layer 310 may be a relatively high-density layer, and the second inorganic encapsulation layer 320 may be a relatively low-density layer. A film density of the second inorganic encapsulation layer 320 may be less than a film density of the third inorganic encapsulation layer 330. That is, the third inorganic encapsulation layer 330 may be a relatively high-density layer, and the second inorganic encapsulation layer may be a relatively low-density layer. For example, in an embodiment, a film density of the first inorganic encapsulation layer 310 may range from about 2.6 g/cm³ to about 3.5 g/cm³. For example, in an embodiment, a film density of the second inorganic encapsulation layer 320 may range from about 1.6 g/cm³ to about 2.3 g/cm³. For example, in an embodiment, a film density of the third inorganic encapsulation layer 330 may range from about 2.6 g/cm³ to about 3.5 g/cm³.

In the area overlapping the pixel openings OP1, OP2, and OP3, because the first inorganic encapsulation layer 310 and the third inorganic encapsulation layer 330, which are high-density layers, are located over and under the second inorganic encapsulation layer 320, which is a low-density layer, the encapsulation layer 300 may prevent penetration of impurities such as oxygen or moisture into the emission areas EA1, EA2, and EA3. In the area overlapping the pixel-defining layer 130, because the third inorganic encapsulation layer 330, which is a high-density layer, is further located on the first inorganic encapsulation layer 310, which is a high-density layer, barrier characteristics of the encapsulation layer 300 for preventing penetration of impurities, such as oxygen or moisture, into the pixel-defining layer 130 may be improved.

In an embodiment, when the second inorganic encapsulation layer 320, which is a low-density layer, is formed directly on the light-emitting elements LED1, LED2, and LED3, due to a low film density, barrier characteristics of the second inorganic encapsulation layer 320 may be lowered. According to an embodiment, because the first inorganic encapsulation layer 310, which has a high density, is first formed and then the second inorganic encapsulation layer 320, which has a low density, is formed on the first inorganic encapsulation layer 310, the first inorganic encapsulation layer 310 may function as a seed layer. Accordingly, the second inorganic encapsulation layer 320 may have a relatively high film density at an interface with the first inorganic encapsulation layer 310 which is disposed adjacent to the second inorganic encapsulation layer 320, as compared to a case where the second inorganic encapsulation layer 320 is formed directly on the light-emitting elements LED1, LED2, and LED3 without forming the first inorganic encapsulation layer 310. Accordingly, the second inorganic encapsulation layer 320 may be formed at a relatively low density to fill and planarize the pixel openings OP1, OP2, and OP3, and also, the barrier characteristics of the second inorganic encapsulation layer 320 may be improved.

In an embodiment, a refractive index of the first inorganic encapsulation layer 310 may be greater than a refractive index of the second inorganic encapsulation layer 320 and a refractive index of the third inorganic encapsulation layer 330 may be greater than a refractive index of the second inorganic encapsulation layer 320. For example, in an embodiment, a refractive index of the first inorganic encapsulation layer 310 may be about 1.85 or more. For example, in an embodiment, a refractive index of the second inorganic encapsulation layer 320 may be about 1.75 to about 1.90. For example, in an embodiment, a refractive index of the third inorganic encapsulation layer 330 may be about 1.85 or more.

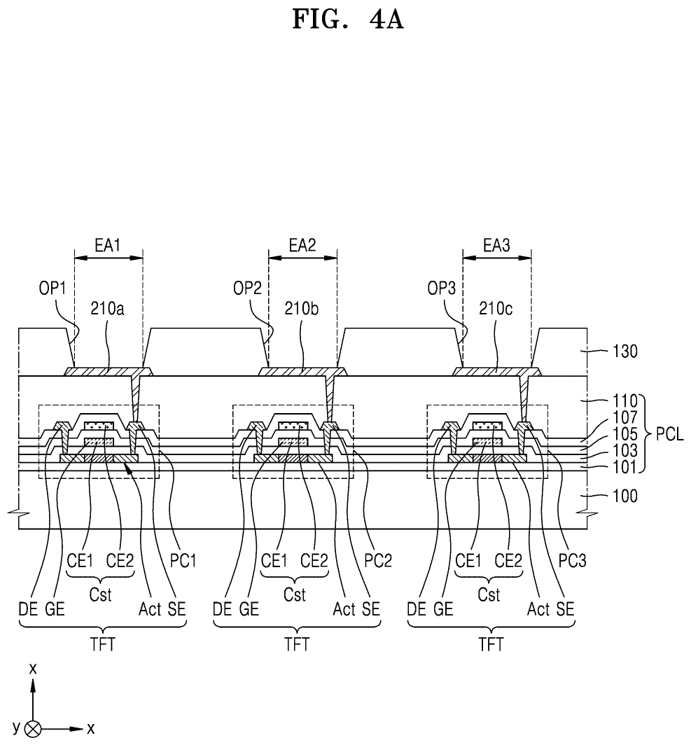

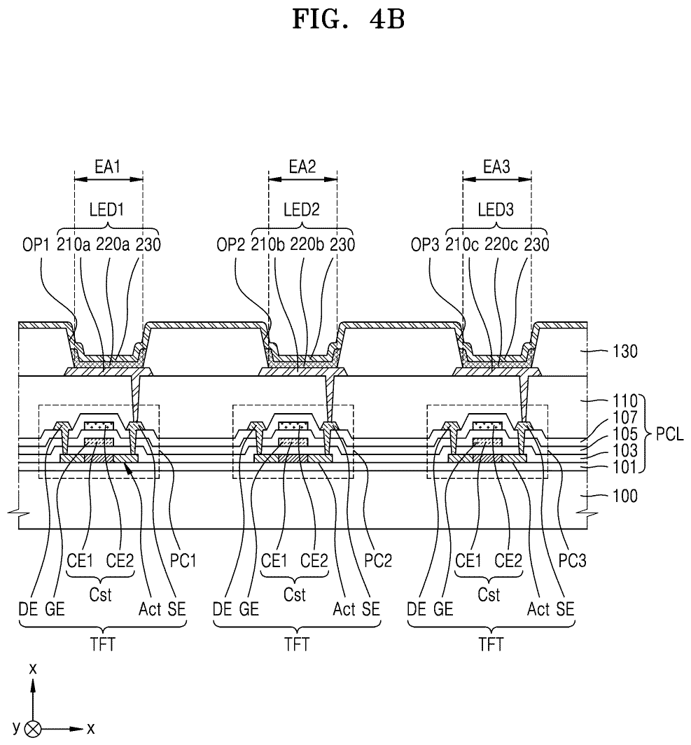

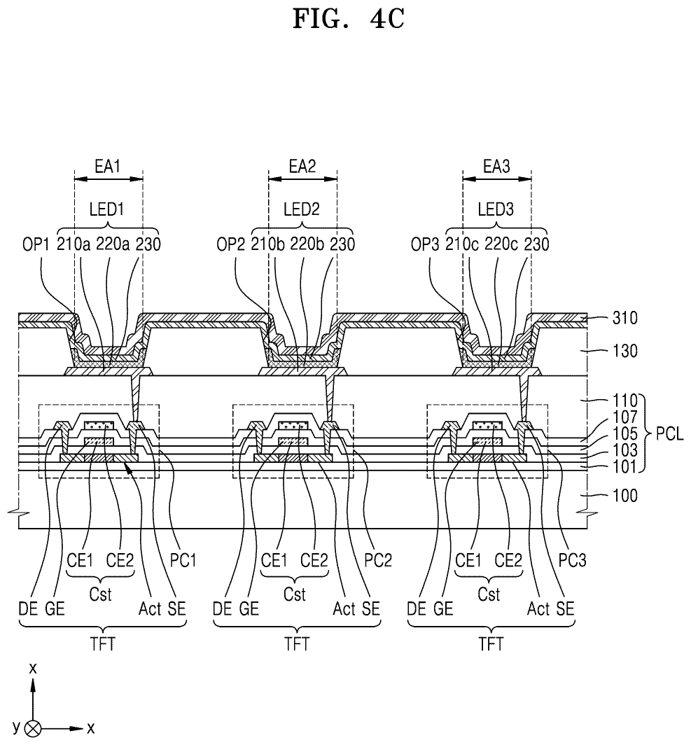

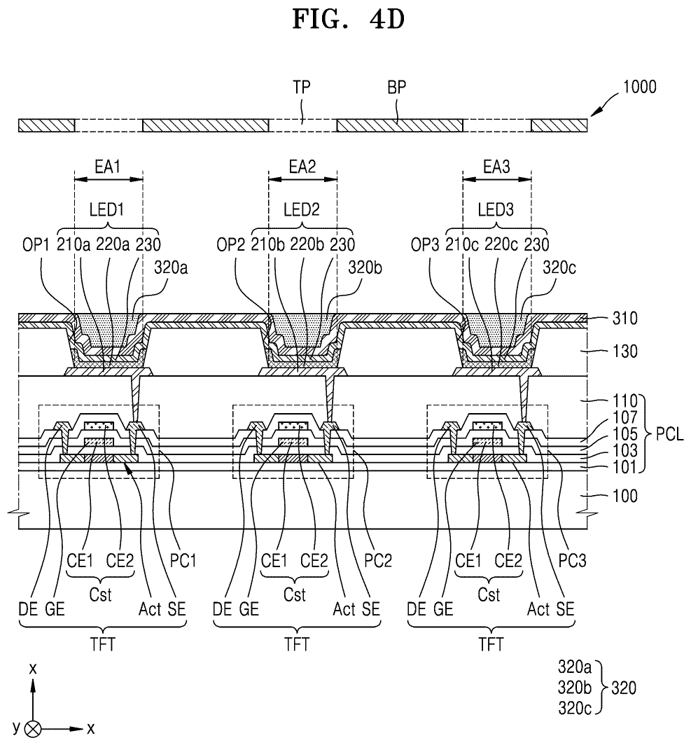

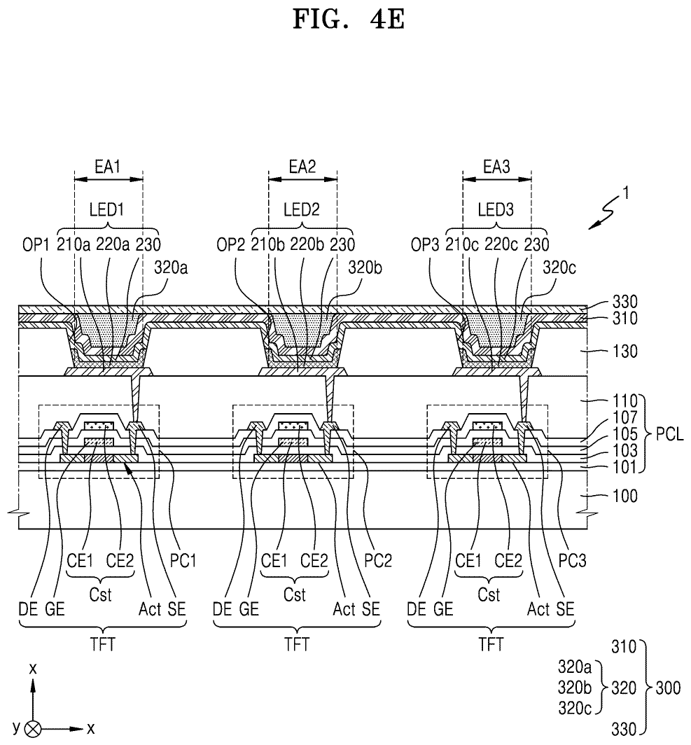

FIGS. 4A to 4E are cross-sectional views schematically illustrating a method of manufacturing a display apparatus, according to an embodiment. FIGS. 4A to 4E sequentially illustrate a manufacturing method according to an embodiment, in a cross-section corresponding to the cross-sectional view of the display apparatus 1 of FIG. 3.

In an embodiment and referring to FIG. 4A, the pixel circuit layer PCL disposed on the substrate 100, the lower electrodes 210a, 210b, and 210c disposed on the pixel circuit layer PCL, and the pixel-defining layer 130 disposed on the lower electrodes 210a, 210b, and 210c on the pixel circuit layer PCL may be formed.

First, according to an embodiment, the pixel circuit layer PCL including pixel circuits PC1, PC2, and PC3 may be formed on the substrate 100. For example, the buffer layer 101, the semiconductor layer Act, the first insulating layer 103, the gate electrode GE, the second insulating layer 105, the second capacitor electrode CE2, the third insulating layer 107, the source/drain electrodes SE and DE, and the fourth insulating layer 110 may be sequentially formed on the substrate 100.

Next, according to an embodiment, the first lower electrode 210a, the second lower electrode 210b and the third lower electrode 210c which are electrically connected to the first pixel circuit PC1, the second pixel circuit PC2 and the third pixel circuit PC3, respectively, may be formed on the pixel circuit layer PCL.

In an embodiment, the lower electrodes 210a, 210b, and 210c may be formed of a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, each of the lower electrodes 210a, 210b, and 210c may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, each of the lower electrodes 210a, 210b, and 210c may further include a film formed of ITO, IZO, ZnO, or In₂O₃ over/under the reflective film.

Next, according to an embodiment, the pixel-defining layer 130 including the first pixel opening OP1 through which a part of the first lower electrode 210a is exposed, the second pixel opening OP2 through which a part of the second lower electrode 210b is exposed, and the pixel opening OP3 through which a part of the third lower electrode 210c is exposed may be formed on the first lower electrode 210a, the second lower electrode 210b and the third lower electrode 210c, respectively. The pixel-defining layer 130 may be formed of an organic material such as polyimide, polyacryl, or hexamethyldisiloxane (HMDSO).

In an embodiment and referring to FIG. 4B, the first intermediate layer 220a, the second intermediate layer 220b and the third intermediate layer 220c may be respectively formed on the first lower electrode 210a, the second lower electrode 210b and the third lower electrode 210c, respectively, and the upper electrode 230 may be formed on the first intermediate layer 220a, the second intermediate layer 220b and the third intermediate layer 220c, to form the first light-emitting element LED1, the second light-emitting element LED2 and the third light-emitting element LED3, respectively.

In an embodiment, each of the intermediate layers 220a, 220b, and 220c may be formed to include an emission layer and a common layer located under/over the emission layer. In an embodiment, the emission layers of the first intermediately layer 220a, the second intermediate layer 220b and the third intermediate layer 220c may be respectively formed in the first pixel opening OP1, the second pixel opening OP2 and the third pixel opening OP3 of the pixel-defining layer 130. For example, the emission layers of the intermediate layers 220a, 220b, and 220c may be organic emission layers formed of organic materials including fluorescent or phosphorescent materials that emit different light. In an embodiment, the common layers of the first intermediate layer 220a, the second intermediately layer 220b and the third intermediate layer 220c may be entirely formed on the display area DA (see FIG. 1) of the substrate 100 to cover the first lower electrode 210a, the second lower electrode 210b and the third lower electrode 210c, respectively.

In an embodiment, the upper electrode 230 may be formed to entirely cover the display area DA (see FIG. 1) of the substrate 100. The upper electrode 230 may be a light-transmitting electrode or a reflective electrode. The upper electrode 230 may be formed of a conductive material having a low work function. For example, in an embodiment, the upper electrode 230 may include a (semi-) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another embodiment, the upper electrode 230 may further include a layer formed of ITO, IZO, ZnO, or In₂O₃ on the (semi-) transparent layer including the above material.

In an embodiment and referring to FIG. 4C, the first inorganic encapsulation layer 310 may be formed on the light-emitting elements LED1, LED2, and LED3. The first inorganic encapsulation layer 310 may be formed on the upper electrode 230. The first inorganic encapsulation layer 310 may be formed to entirely cover the display area DA (see FIG. 1) of the substrate 100. For example, the first inorganic encapsulation layer 310 may overlap the pixel openings OP1, OP2, and OP3 and may overlap the pixel-defining layer 130.

In an embodiment, the first inorganic encapsulation layer 310 may be formed as a high-density layer having a higher film density than the second inorganic encapsulation layer 320. For example, in an embodiment, a film density of the first inorganic encapsulation layer 310 may range from about 2.6 g/cm³ to about 3.5 g/cm³.

In an embodiment, the first inorganic encapsulation layer 310 may be formed by using a deposition process. For example, in an embodiment, the first inorganic encapsulation layer 310 may be deposited at a deposition rate of less than about 300 Å/min. For example, the first inorganic encapsulation layer 310 may be formed by using atomic layer deposition (ALD) or chemical vapor deposition (CVD). For example, in an embodiment, the first inorganic encapsulation layer 310 may be formed by using plasma enhanced ALD (PEALD) or plasma enhanced CVD (PECVD). For example, in an embodiment, a thickness of the first inorganic encapsulation layer 310 may range from about 10 Å to about 100 Å.

In an embodiment, the first inorganic encapsulation layer 310 may include an inorganic material. For example, the first inorganic encapsulation layer 310 may include an inorganic material such as silicon nitride (SiNₓ), silicon oxide (SiOₓ), or silicon oxynitride (SiOₓN_{y}).

In an embodiment, the first inorganic encapsulation layer 310 may be formed by using a compound including a silicon element and a nitrogen element as a precursor. For example, the first inorganic encapsulation layer 310 may be formed by using a silicon amine-based compound as a precursor. In this case, the first inorganic encapsulation layer 310 may be formed to include an inorganic material including at least a silicon (Si) element and a nitrogen (N) element. For example, in an embodiment, the first inorganic encapsulation layer 310 may include silicon nitride (SiNₓ) or silicon oxynitride (SiOₓN_{y}). For example, in an embodiment, a ratio of the nitrogen element to the silicon element of the first inorganic encapsulation layer 310 may be less than about 0.75. For example, a refractive index of the first inorganic encapsulation layer 3.10 may be about 1.85 or more.

In an embodiment and referring to FIG. 4D, the second inorganic encapsulation layer 320 may be formed on the first inorganic encapsulation layer 310, where the second inorganic encapsulation layer 320 may be a low-density layer. For example, the second inorganic encapsulation layer 320 may be formed as a low-density layer having a lower film density than the first inorganic encapsulation layer 310. For example, in an embodiment, a film density of the second inorganic encapsulation layer 320 may range from about 1.6 g/cm³ to about 2.3 g/cm³.

In an embodiment, the second inorganic encapsulation layer 320 may be formed by using a mask 1000 including an opening portion TP and a blocking portion BP. The mask 1000 may be a mask for deposition. In detail, the opening portion TP of the mask 1000 may be located to overlap each of the light-emitting elements LED1, LED2, and LED3 or the pixel openings OP1, OP2, and OP3, and the blocking portion BP of the mask 1000 may be located to overlap the pixel-defining layer 130. Accordingly, the second inorganic encapsulation layer 320 may be deposited in each of the pixel openings OP1, OP2, and OP3 through the opening portion TP of the mask 1000.

In an embodiment, the second inorganic encapsulation layer 320 may include a plurality of inorganic encapsulation patterns which are spaced apart from each other. For example, the first inorganic encapsulation pattern 320a may be formed in the first pixel opening OP1, the second inorganic encapsulation pattern 320b may be formed in the second pixel opening OP2, and the third inorganic encapsulation pattern 320c may be formed in the third pixel opening OP3. The inorganic encapsulation patterns 320a, 320b, and 320c may be spaced apart from each other.

Because the second inorganic encapsulation layer 320 is formed as a low-density layer ranging from about 1.6 g/cm³ to about 2.30 g/cm³, the second inorganic encapsulation layer 320 may be formed to fill each of the pixel openings OP1, OP2, and OP3. That is, the first inorganic encapsulation pattern 320a, the second inorganic encapsulation pattern 320b, and the third inorganic encapsulation pattern 320c may be formed to respectively fill the first pixel opening OP1, the second pixel opening OP2, and the third pixel opening OP3. Additionally, a water vapor transmission rate (WVTR) of the second inorganic encapsulation layer 320 may be equal to or greater than about 2*10⁻⁴ g/m² day and less than about 4*10⁻⁴ g/m² day.

In an embodiment, a top surface of the second inorganic encapsulation layer 320 may be located at substantially the same level as a top surface of a portion of the first inorganic encapsulation layer 310 which overlaps the pixel-defining layer 130. Accordingly, the top surfaces of the first inorganic encapsulation layer 310 and the second inorganic encapsulation layer 320 may form substantially one flat top surface.

In an embodiment, the second inorganic encapsulation layer 320 may be formed by using a deposition process. The second inorganic encapsulation layer 320 may be deposited at a higher deposition rate than the first inorganic encapsulation layer 310. For example, in an embodiment, the second inorganic encapsulation layer 320 may be deposited at a deposition rate of about 300 Å/min or more. For example, in an embodiment, the second inorganic encapsulation layer 320 may be formed by using ALD or CVD. For example, the second inorganic encapsulation layer 320 may be formed by using PEALD or PECVD. A thickness of the second inorganic encapsulation layer 320 may be greater than a thickness of the first inorganic encapsulation layer 310. For example, in an embodiment, a thickness of the second inorganic encapsulation layer 320 may be greater than about 100 Å.

In an embodiment, the second inorganic encapsulation layer 320 may include an inorganic material. For example, the second inorganic encapsulation layer 320 may include an inorganic material such as silicon nitride (SiNₓ), silicon oxide (SiOₓ), or silicon oxynitride (SiOₓN_{y}).

In an embodiment, the second inorganic encapsulation layer 320 may be formed by using a compound including a silicon element and a nitrogen element as a precursor. For example, the second inorganic encapsulation layer 320 may be formed by using a silicon amine-based compound as a precursor. In this case, the second inorganic encapsulation layer 320 may be formed to include an inorganic material including at least a silicon (Si) element and a nitrogen (N) element. For example, in an embodiment, the second inorganic encapsulation layer 320 may include silicon nitride (SiNₓ) or silicon oxynitride (SiOₓN_{y}). A ratio (N/Si ratio) of the nitrogen element to the silicon element of the second inorganic encapsulation layer 320 may be greater than a ratio (N/Si ratio) of the nitrogen element to the silicon element of the first inorganic encapsulation layer 310. For example, in an embodiment, a ratio of the nitrogen element to the silicon element of the second inorganic encapsulation layer 320 may be greater than about 0.77. A refractive index of the second inorganic encapsulation layer 320 may be less than a refractive index of the first inorganic encapsulation layer 310. For example, in an embodiment, a refractive index of the second inorganic encapsulation layer 320 may be in a range of about 1.75 to about 1.90.

In an embodiment and referring to FIG. 4E, the third inorganic encapsulation layer 330 may be formed on the second inorganic encapsulation layer 320. The third inorganic encapsulation layer 330 may be formed to entirely cover the display area DA (see FIG. 1) of the substrate 100. For example, the third inorganic encapsulation layer 330 may overlap the pixel openings OP1, OP2, and OP3 and may overlap the pixel-defining layer 130.

In an embodiment, the third inorganic encapsulation layer 330 may be spaced apart from the first inorganic encapsulation layer 310 in an area that overlaps the pixel openings OP1, OP2, and OP3 and may be located directly on the first inorganic encapsulation layer 310 in an area that overlaps the pixel-defining layer 130. In other words, in the area overlapping the pixel-defining layer 130, the third inorganic encapsulation layer 330 may contact the first inorganic encapsulation layer 310.

In an embodiment, the third inorganic encapsulation layer 330 may be formed as a high-density layer having a higher film density than the second inorganic encapsulation layer 320. For example, in an embodiment, a film density of the third inorganic encapsulation layer 330 may range from about 2.6 g/cm³ to about 3.5 g/cm³.

In an embodiment, the third inorganic encapsulation layer 330 may be formed by using a deposition process, where the third inorganic encapsulation layer 330 may be deposited at a lower deposition rate than the second inorganic encapsulation layer 320. For example, in an embodiment, the third inorganic encapsulation layer 330 may be deposited at a deposition rate of less than about 300 Å/min. For example, in an embodiment, the third inorganic encapsulation layer 330 may be formed by using ALD or CVD. For example, the third inorganic encapsulation layer 330 may be formed by using PEALD or PECVD. For example, in an embodiment, a thickness of the third inorganic encapsulation layer 330 may range from, but not be limited to, about 10 Å to about 100 Å. According to an embodiment, the third inorganic encapsulation layer 330 may have a thickness exceeding about 100 Å.

According to an embodiment, in the area overlapping the first pixel opening OP1, the second pixel opening OP2 and the third pixel opening OP3, the encapsulation layer 300 may include the first inorganic encapsulation layer 310, the second inorganic encapsulation layer 320 and the third inorganic encapsulation layer 330, and in the area overlapping the pixel-defining layer 130, the encapsulation layer 300 may include the first inorganic encapsulation layer 310 and the third inorganic encapsulation layer 330, but may exclude the second inorganic encapsulation layer 320. As the second inorganic encapsulation layer 320 is located to overlap only the pixel openings OP1, OP2, and OP3, the thickness Tb (See FIG. 3) of the encapsulation layer 300 located on the pixel-defining layer 130 may be as small as about 1 μm or less. In an embodiment, in the area overlapping the pixel-defining layer 130, the thickness Tb of the encapsulation layer 300 may be in the range of about 0.002 μm to about 0.02 μm.

As a display apparatus, according to an embodiment, includes a first inorganic encapsulation layer, a second inorganic encapsulation layer located on the first inorganic encapsulation layer and in a pixel opening of a pixel-defining layer, and a third inorganic encapsulation layer located on the second inorganic encapsulation layer, a thin display apparatus may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. A display apparatus comprising:
a substrate;
a lower electrode located on the substrate;
a pixel-defining layer located on the lower electrode and comprising a pixel opening through which a part of the lower electrode is exposed;
an intermediate layer located on the lower electrode and comprising an emission layer;
an upper electrode located on the intermediate layer;
a first inorganic encapsulation layer located on the upper electrode;
a second inorganic encapsulation layer located on the first inorganic encapsulation layer and located in the pixel opening; and
a third inorganic encapsulation layer located on the second inorganic encapsulation layer,
wherein the third inorganic encapsulation layer is spaced apart from the first inorganic encapsulation layer in an area overlapping the pixel opening and is located directly on the first inorganic encapsulation layer in an area overlapping the pixel-defining layer.

2. The display apparatus of claim 1, wherein a film density of the second inorganic encapsulation layer is lower than a film density of the first inorganic encapsulation layer.

3. The display apparatus of claim 1, wherein a film density of the second inorganic encapsulation layer is lower than a film density of the third inorganic encapsulation layer.

4. The display apparatus of claim 1, wherein the second inorganic encapsulation layer does not overlap the pixel-defining layer.

5. The display apparatus of claim 1, wherein the second inorganic encapsulation layer fills the pixel opening.

6. The display apparatus of claim 1, wherein each of the first inorganic encapsulation layer and the third inorganic encapsulation layer overlaps the pixel opening and the pixel-defining layer.

7. The display apparatus of claim 1, wherein a film density of the first inorganic encapsulation layer is in a range of about 2.6 g/cm³ to about 3.5 g/cm³.

8. The display apparatus of claim 1, wherein a film density of the second inorganic encapsulation layer is in a range of about 1.6 g/cm³ to about 2.3 g/cm³.

9. The display apparatus of claim 1, wherein a film density of the third inorganic encapsulation layer is in a range of about 2.6 g/cm³ to about 3.5 g/cm³.

10. The display apparatus of claim 1, wherein each of the first inorganic encapsulation layer and the second inorganic encapsulation layer comprises a silicon element and a nitrogen element, and
wherein a ratio of the nitrogen element of the first inorganic encapsulation layer to the silicon element of the first inorganic encapsulation layer is less than a ratio of the nitrogen element of the second inorganic encapsulation layer to the silicon element of the second inorganic encapsulation layer.

11. The display apparatus of claim 1, wherein a refractive index of the first inorganic encapsulation layer is greater than a refractive index of the second inorganic encapsulation layer.

12. A display apparatus comprising:
a substrate;
a first light-emitting element, a second light-emitting element, and a third light-emitting element, wherein each of the first light-emitting element, the second light-emitting element and the third light-emitting element are located on the substrate and configured to emit light of different colors; and
an encapsulation layer located on the first light-emitting element, the second light-emitting element and the third light-emitting element to encapsulate the first light-emitting element, the second light-emitting element and the third light-emitting element,
wherein the encapsulation layer comprises:
a first inorganic encapsulation layer located on the first light-emitting element, the second light-emitting element and the third light-emitting element;
a second inorganic encapsulation layer located on the first inorganic encapsulation layer, having a film density lower than a film density of the first inorganic encapsulation layer, and comprising a first inorganic encapsulation pattern overlapping the first light-emitting element, a second inorganic encapsulation pattern overlapping the second light-emitting element, and a third inorganic encapsulation pattern overlapping the third light-emitting element; and
a third inorganic encapsulation layer located on the second inorganic encapsulation layer,
wherein the first inorganic encapsulation pattern, the second inorganic encapsulation pattern, and the third inorganic encapsulation pattern are spaced apart from each other.

13. The display apparatus of claim 12, wherein each of the first light-emitting element, the second light-emitting element and the third light-emitting element comprises a lower electrode, an emission layer located on the lower electrode, and an upper electrode located on the emission layer,
wherein the display apparatus further comprises a pixel-defining layer comprising a first pixel opening through which a part of the lower electrode of the first light-emitting element is exposed, a second pixel opening through which a part of the lower electrode of the second light-emitting element is exposed, and a third pixel opening through which a part of the lower electrode of the third light-emitting element is exposed,
wherein the first inorganic encapsulation pattern is located in the first pixel opening,
the second inorganic encapsulation pattern is located in the second pixel opening, and
the third inorganic encapsulation pattern is located in the third pixel opening.

14. The display apparatus of claim 13, wherein each of the first inorganic encapsulation pattern, the second inorganic encapsulation pattern and the third inorganic encapsulation pattern do not overlap the pixel-defining layer.

15. The display apparatus of claim 13, wherein the third inorganic encapsulation layer is spaced apart from the first inorganic encapsulation layer in an area overlapping the first pixel opening, the second pixel opening and the third pixel opening and is located directly on the first inorganic encapsulation layer in an area overlapping the pixel-defining layer.

16. The display apparatus of claim 13, wherein each of the first inorganic encapsulation layer and the third inorganic encapsulation layer overlap the first pixel opening, the second pixel opening and the third pixel opening and the pixel-defining layer.

17. The display apparatus of claim 12, wherein a film density of the third inorganic encapsulation layer is greater than a film density of the second inorganic encapsulation layer.

18. A method of manufacturing a display apparatus, the method comprising:
forming, on a lower electrode, a pixel-defining layer having a pixel opening through which a part of the lower electrode is exposed;
forming an emission layer on the lower electrode;
forming an upper electrode on the emission layer;
forming a first inorganic encapsulation layer on the upper electrode;
forming a second inorganic encapsulation layer on the first inorganic encapsulation layer to fill the pixel opening by using a mask having an opening located in an area overlapping the pixel opening; and
forming a third inorganic encapsulation layer on the second inorganic encapsulation layer,
wherein a film density of the second inorganic encapsulation layer is lower than a film density of the first inorganic encapsulation layer.

19. The method of claim 18, wherein the third inorganic encapsulation layer is spaced apart from the first inorganic encapsulation layer in the area overlapping the pixel opening and is located directly on the first inorganic encapsulation layer in an area overlapping the pixel-defining layer.

20. The method of claim 18, wherein a deposition rate of the second inorganic encapsulation layer is greater than a deposition rate of the first inorganic encapsulation layer.

21. The method of claim 18, wherein a deposition rate of the third inorganic encapsulation layer is less than a deposition rate of the second inorganic encapsulation layer.

22. The method of claim 18, wherein a film density of the second inorganic encapsulation layer is lower than a film density of the third inorganic encapsulation layer.
